(19) United States
(12) Patent Application Publication
(10) Pub. No.: US 2026/0101622 A1
(43) Pub. Date: Apr. 9, 2026

(54) DISPLAY DEVICE AND METHOD FOR MANUFACTURING THE SAME

(71) Applicant: Samsung Display Co., LTD., Yongin-si (KR)

(72) Inventor: Hyun Deok IM, Yongin-si (KR)

(73) Assignee: Samsung Display Co., LTD., Yongin-si (KR)

(21) Appl. No.: 19/298,671

(22) Filed: Aug. 13, 2025

(30) Foreign Application Priority Data
Oct. 7, 2024 (KR) 10-2024-0135477

(51) Int. Cl. H10H 29/49; H10H 29/01; H10H 29/856

(52) U.S. Cl. CPC H10H 29/49; H10H 29/012; H10H 29/856

(57) ABSTRACT

A display device and a method of manufacturing the display device are provided. The display device includes a substrate, a pixel electrode and a common electrode disposed on the substrate disposed apart from each other on the substrate, a light emitting element structure disposed on the common electrode, and including a light emitting pillar and a plurality of dummy pillars surrounding the light emitting pillar and a connection electrode connecting the light emitting pillar and the pixel electrode, wherein the light emitting element structure includes, a reflective layer surrounding an upper surface and a side surface of the dummy pillar and a protective layer surrounding the upper surface and the side surface of the dummy pillar and an upper surface and a side surface of the light emitting pillar.

### CROSS-REFERENCE TO RELATED APPLICATION(S)

This application claims priority to and the benefits of Korean Patent Application No. 10-2024-0135477 under 35 U.S.C. § 119, filed Oct. 7, 2024, in the Korean Intellectual Property Office, the entire contents of which are incorporated herein by reference.

### BACKGROUND

### 1. Technical Field

The disclosure relates to a display device and a method for manufacturing the display device.

### 2. Description of the Related Art

As the information society develops, demands for display devices for displaying images are increasing in various forms. The display devices may be flat panel display devices such as liquid crystal displays, field emission displays, and light emitting displays.

The light emitting displays include an organic light emitting display including an organic light emitting diode (OLED) element as a light emitting element and a micro-light emitting display including a micro-light emitting diode element (hereinafter, referred to as a micro-light emitting element) as a light emitting element. Because micro-light emitting diode elements are made of inorganic materials, they have less deterioration issues and thus a longer life than organic light emitting diode (OLED) elements.

### SUMMARY

Aspects and features of embodiments of the disclosure are to provide a display device including a light emitting element structure capable of increasing the light emitting efficiency of a light emitting element and a method for manufacturing the same.

However, the disclosure is not limited to those set forth herein. The above and other embodiments of the disclosure will become more apparent to one of ordinary skill in the art to which the disclosure pertains by referencing the detailed description of the disclosure given below.

According to one or more embodiments of the disclosure, a display device includes a substrate, a pixel electrode and a common electrode disposed on the substrate disposed apart from each other on the substrate, a light emitting element structure disposed on the common electrode, and including a light emitting pillar and a plurality of dummy pillars surrounding the light emitting pillar and a connection electrode connecting the light emitting pillar and the pixel electrode, wherein the light emitting element structure includes a reflective layer surrounding an upper surface and a side surface of the dummy pillar and a protective layer surrounding the upper surface and the side surface of the dummy pillar and the upper surface and the side surface of the light emitting pillar.

According to one or more embodiments, the light emitting pillar may have a first inclination angle between a lower surface and a side surface of the light emitting pillar, wherein the dummy pillar may have a second inclination angle that is between the lower surface and the side surface of the dummy pillar, wherein the second inclination angle may be different from the second inclination angle.

According to one or more embodiments, the second inclination angle may be smaller than the first inclination angle.

According to one or more embodiments, a width of the dummy pillar may decrease as a distance from the substrate increases on the substrate, and the upper surface and a lower surface of the light emitting pillar may have the same width at the top and bottom portions.

According to one or more embodiments, the light emitting element structure may further include an element reflective layer on a lower surface, a plurality of semiconductor layers disposed on the element reflective layer, and a conductive layer disposed on the plurality of semiconductor layers.

According to one or more embodiments, the plurality of semiconductor layers may include, a second semiconductor layer including a first portion having a first height and a second portion having a second height on the first portion, an active layer disposed on the second semiconductor layer, a first semiconductor layer disposed on the active layer.

According to one or more embodiments, the dummy pillar and the light emitting pillar may each include a second semiconductor layer including the second portion, the active layer, the first semiconductor layer, and the conductive layer.

According to one or more embodiments, the protective layer may include an opening exposing a portion of the conductive layer of the light emitting pillar, and wherein the connection electrode may be electrically connected to the conductive layer through the opening.

According to one or more embodiments, the display device may include a planarization layer disposed on the light emitting element structure and a second protective layer disposed on an upper surface of the planarization layer and a side surface of the light emitting element structure and including an opening overlapping an opening of the protective layer.

According to one or more embodiments, the display device may further include a partition wall disposed to surround the light emitting element structure, a third reflective layer disposed on a side surface of the partition wall, and a wavelength conversion layer disposed in a space formed by the partition wall.

According to one or more embodiments, the light emitting element structure may not overlap the partition wall.

According to one or more embodiments, the light emitting element structure may not overlap the light emitting pillar but overlap a portion of the dummy pillar.

According to one or more embodiments, the dummy pillar may be circular or polygonal in a plan view, wherein the light emitting pillar may be circular or polygonal in a plan view.

According to one or more embodiments, the dummy pillar and the light emitting pillar may be a same shape in a plan view.

According to one or more embodiments, the dummy pillar and the light emitting pillar may have different shapes in a plan view.

According to one or more embodiments of the disclosure, a method for manufacturing a display device includes forming a second semiconductor material layer, an active material layer, a first semiconductor material layer, and a conductive material layer on a semiconductor substrate, first etching the second semiconductor material layer, the active material layer, the first semiconductor material layer, and the conductive material layer to form a plurality of pillars each including the second semiconductor material layer, the active material layer, the first semiconductor material layer, and the conductive material layer, forming a reflective layer including openings in some of the pillars among the plurality of pillars, and second etching the pillars on which the reflective layer is not disposed and the forming a protective layer including an opening on entire surface of the semiconductor substrate on the pillars on which the reflective layer is not disposed.

According to one or more embodiments, the first etching may be dry etching, and the second etching may be wet etching.

According to one or more embodiments, among the plurality of pillars, the pillars whose upper surfaces and side surfaces are surrounded by the reflective layer may be dummy pillars, and the pillars on which the upper surfaces and the side surfaces are not formed by the openings may be light emitting pillars, and the light emitting pillars and the dummy pillars may have different inclinations by the second etching.

The method may further include separating a light emitting element structure including the light emitting pillar and the dummy pillar from the semiconductor substrate and transferring the light emitting pillar and the dummy pillar onto a circuit substrate including a pixel electrode and a common electrode and forming a connection electrode connecting the pixel electrode and the light emitting pillars.

According to one or more embodiments, an electronic device includes: a display panel including: a substrate; a pixel electrode and a common electrode disposed on the substrate disposed apart from each other on the substrate; a light emitting element structure disposed on the common electrode, and including a light emitting pillar and a plurality of dummy pillars surrounding the light emitting pillar; and a connection electrode connecting the light emitting pillar and the pixel electrode; wherein the light emitting element structure includes: a reflective layer surrounding an upper surface and a side surface of the dummy pillar; and a protective layer surrounding the upper surface and the side surface of the dummy pillar and the upper surface and a side surface of the light emitting pillar.

According to the display device and its manufacturing method according to the embodiments, the light emitting efficiency of the display device may be increased.

According to one or more embodiments of the disclosure, a contact electrode of a light emitting element is spaced from an upper surface of a semiconductor stack. Therefore, the contact electrode can be prevented from being peeled off by a chemical solution or the like, unlike when exposed on the upper surface of the semiconductor stack.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment.

FIG. 2 is a schematic layout illustrating a display device according to an embodiment.

FIG. 3 is a schematic block diagram illustrating a display device according to an embodiment.

FIG. 4 is a schematic diagram of an equivalent circuit of a sub-pixel according to an embodiment.

FIG. 5 is a schematic layout illustrating pixels of a display area according to an embodiment.

FIG. 6 is a schematic cross-sectional view illustrating an example of a cross-section of a display panel taken along lines I1-I1′, I2-I2′, and I3-I3′ in FIG. 5.

FIG. 7 is a schematic cross-sectional view illustrating an example of area A1 of FIG. 6 in detail.

FIG. 8 is a schematic diagram illustrating a light emitting element structure according to an embodiment.

FIG. 9 is a schematic layout diagram illustrating pixels in a display area according to another embodiment.

FIG. 10 is a schematic cross-sectional view illustrating an example of a portion of a cross-section of a display panel in a third light emitting area of FIG. 9.

FIG. 11 is a schematic flowchart illustrating a method for manufacturing a display device according to an embodiment.

FIGS. 12 to 22 are schematic cross-sectional views illustrating a method for manufacturing a display device according to an embodiment.

FIGS. 23 to 26 are schematic plan views illustrating positions of dummy pillars and light emitting pillars in a sub-pixel according to an embodiment.

FIGS. 27 and 28 are schematic plan views illustrating positions of dummy pillars and light emitting pillars in a sub-pixel according to another embodiment.

FIG. 29 is a block diagram of an electronic device according to one embodiment.

FIG. 30 is a schematic diagram of an electronic device according to various embodiments.

### BRIEF DESCRIPTION OF THE EMBODIMENTS

Aspects and features of embodiments of the disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the disclosure will be thorough and complete, and will fully convey the aspects and features of the disclosure to those skilled in the art. Accordingly, processes, elements, and techniques that are not necessary to those having ordinary skill in the art for a complete understanding of the aspects and features of the disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the disclosure refers to “one or more embodiments of the disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the disclosure refers to “one or more embodiments of the disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

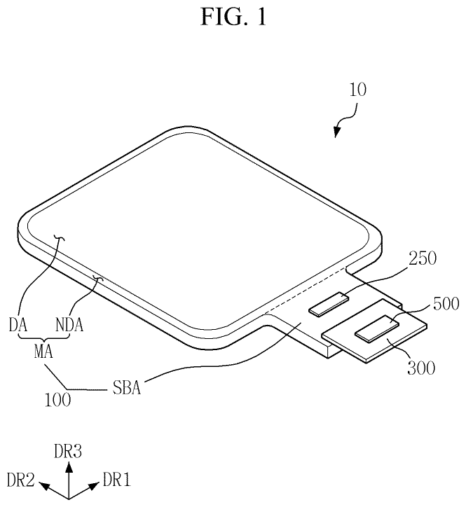

FIG. 1 is a schematic perspective view illustrating a display device according to an embodiment.

Referring to FIG. 1, a display device 10 may be for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and the internet of things (IOT).

The display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the disclosure is not limited thereto. On the other hand, hereinafter, an ultra-small light emitting diode is described as a light emitting element for convenience of explanation.

The display device 10 may include a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a selected curvature or may be formed at a right angle. The planar shape of the display panel 100 is not limited to a rectangle, but may be formed in other polygonal, circular, or oval shapes. The display panel 100 may be formed flat but is not limited thereto. For example, the display panel 100 may be formed at the left and right ends and may include curved portions with a constant curvature or a changing curvature. The display panel 100 may be flexibly formed to be bent, curved, bent, folded, or rolled.

The substrate SUB of the display panel 100 may include a main area MA and a sub-area SBA.

The main area MA may include a display area DA that displays an image and a non-display area NDA that is a surrounding area of the display area DA. The display area DA may include multiple pixels that display an image. Each pixel may include multiple sub-pixels. For example, each of the pixels may include a first sub-pixel that emits light of a first color, a second sub-pixel that emits light of a second color, and a third sub-pixel that emits light of a third color. However, the embodiments of the disclosure are not limited thereto.

The sub-area SBA may protrude from a side of the main area MA in the second direction DR2. Although FIG. 1 illustrates the sub-area SBA being unfolded, the sub-area SBA may be bent, and for example, may be disposed on the lower surface of the display panel 100. In case that the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. The display driving circuit 250 may be attached to the circuit substrate 300 using a chip on film (COF) method.

The circuit substrate 300 may be attached to an end of the sub-area SBA of the display panel 100. For example, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate multiple panel driving voltages according to an external power supply voltage. The power supply circuit 500 may be formed as an integrated circuit (IC) and attached to the circuit substrate 300 using a COF method.

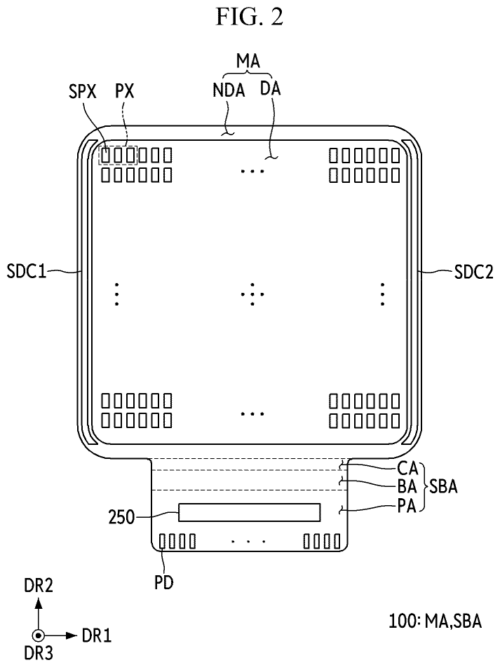

FIG. 2 is a schematic layout illustrating a display device according to an embodiment. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be disposed in the center of the main area MA.

The display area DA may include multiple pixels PX for displaying an image, and each of multiple pixels PX may include multiple sub-pixels SPX. A pixel PX may be defined as a sub-pixel group of the smallest unit capable of expressing a white grayscale.

The non-display area NDA may be disposed adjacent to the display area DA. The non-display area NDA may be an area disposed outside the display area DA. The non-display area NDA may be arranged to surround the display area DA. The non-display area NDA may be an edge area of the display panel 100.

A first scan driving portion SDC1 and a second scan driving portion SDC2 may be disposed in the non-display area NDA. The first scan driving portion SDC1 may be disposed on a side (e.g., the left side) of the display panel 100, and the second scan driving portion SDC2 may be disposed on another side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from a side of the main area MA in the second direction DR2. The length of the sub-area SBA in the second direction DR2 may be smaller than the length of the main area MA in the second direction DR2. The length of the first direction DR1 of the sub-area SBA may be less than the length of the first direction DR1 of the main area MA or may be substantially equal to the length of the first direction DR1 of the main area MA. The sub-area SBA may be curved and may be disposed at a lower portion of the display panel 100. For example, the sub-area SBA may overlap the main area MA in the third direction DR3.

The sub-area SBA may include a connection area CA, a pad area PA, and a bending area BA.

The connection area CA may be an area protruding from a side of the main area MA in the second direction DR2. A side of the connection area CA may be in contact with the non-display area NDA of the main area MA, and another side of the connection area CA may be in contact with the bending area BA.

The pad area PA may be an area where the pads PD and the display driving circuit 250 may be disposed. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. A side of the pad area PA may be in contact with the bending area BA.

The bending area BA may be a bent area. In case that the bending area BA is bent, the pad area PA may be disposed below the connection area CA and below the main area MA. The bending area BA may be disposed between the connection area CA and the pad area PA. A side of the bending area BA may be in contact with the connection area CA, and another side of the bending area BA may be in contact with the pad area PA.

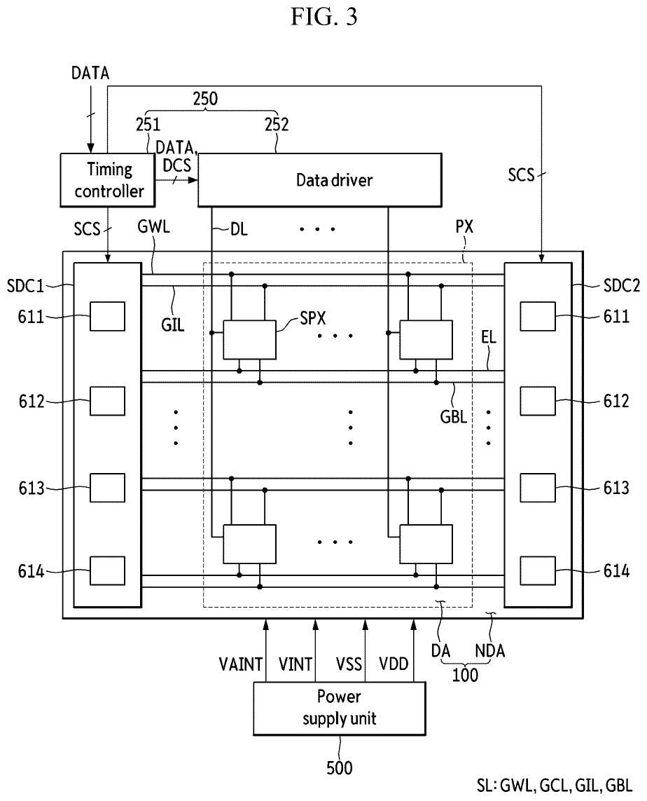

FIG. 3 is a schematic block diagram illustrating a display device according to an embodiment.

Referring to FIG. 3, the display area DA may include multiple pixels PX, multiple scan lines SL, multiple emission control lines EL, and multiple data lines DL.

Multiple pixels PX may be arranged in a matrix form in the first direction DR1 and the second direction DR2. Multiple scan lines SL and multiple emission control lines EL may extend in the first direction DR1 and be disposed in the second direction DR2. Multiple data lines DL may extend in the second direction DR2 and be disposed in the first direction DR1. Multiple scan lines SL may include a multiple write scan lines GWL, multiple initialization scan lines GIL, and multiple bias scan lines GBL.

Each of multiple sub-pixels SPX may be electrically connected to a write scan line GWL from among multiple write scan lines GWL, an initialization scan line GIL from among multiple initialization scan lines GIL, a bias scan line GBL from among multiple bias scan lines GBL, an emission control line EL from among multiple emission control lines EL, and a data line DL from among multiple data lines DL. Each of multiple sub-pixels SPX may be supplied with a data voltage of the data line DL according to the write scan signal of the write scan line GWL and may emit light emitting elements according to the data voltage.

The non-display area NDA may include a first scan driving portion SDC1, a second scan driving portion SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 may include a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. For example, the sub-pixels SPX may be selected by the write scan signals of the first scan driving portion SDC1 and the second scan driving portion SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit 500 may generate multiple panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

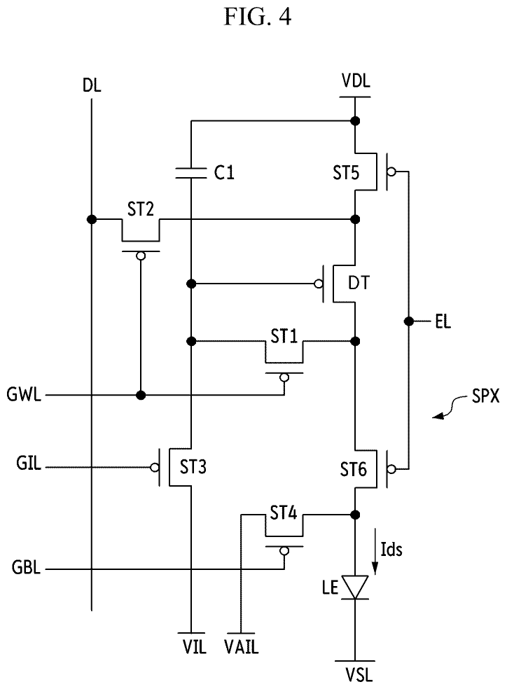

FIG. 4 is a schematic diagram of an equivalent circuit of a sub-pixel according to an embodiment.

Referring to FIG. 4, a sub-pixel SPX according to an embodiment may be electrically connected to scan lines GWL, GIL, and GBL, an emission control line EL, and a data line DL. For example, the sub-pixel SPX may be electrically connected to a write scan line GWL, an initialization scan line GIL, a bias scan line GBL, an emission control line EL, and a data line DL.

The sub-pixel SPX according to an embodiment may include a driving transistor DT, switching elements, a capacitor, and a light emitting element LE. The switching elements include first to sixth transistors ST1, ST2, ST3, ST4, ST5, and ST6.

The driving transistor DT may include a gate electrode, a first electrode, and a second electrode. The driving transistor DT controls a drain-source current (Ids, hereinafter referred to as “driving current”) flowing between the first electrode and the second electrode according to a data voltage applied to a gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE may be electrically connected to the first electrode of the fourth transistor ST4 and the second electrode of the sixth transistor ST6, and the cathode electrode may be electrically connected to a second power supply line VSL to which a second power supply voltage is applied.

A capacitor C1 may be formed between a gate electrode of a driving transistor DT and a first power supply line VDL to which a first power supply voltage is applied. The first power supply voltage may be a voltage of a higher level than the second power supply voltage. An electrode of the capacitor C1 may be electrically connected to the gate electrode of the driving transistor DT, and another electrode may be electrically connected to the first power supply line VDL.

As shown in FIG. 4, the first to sixth transistors ST1, ST2, ST3, ST4, ST5, and ST6 and the driving transistor DT may all be formed as p-type MOSFET. For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Since the first to sixth transistors ST1, ST2, ST3, ST4, ST5, and ST6 may be formed as p-type MOSFET and they may be turned on in case that a scan signal of a gate low voltage and an emission control signal are applied to the initialization scan line GIL, the write scan line GWL, the bias scan line GBL, and the emission control line EL, respectively. An electrode of the third transistor ST3 may be connected to a first initialization voltage line VIL to which the third power supply voltage (VINT of FIG. 3) is applied, and an electrode of the fourth transistor ST4 may be connected to a second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

In another embodiment, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. For example, the active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor. Furthermore, since the first transistor ST1 and the third transistor ST3 may be formed as n-type MOSFET, the first transistor ST1 may be turned on in case that a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 may be formed as p-type MOSFET so that they may be turned on in case that a scan signal of the gate low voltage and a light emission control signal are applied.

In another embodiment, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on in case that a scan signal of a gate high voltage is applied, whereas the remaining transistors DT, ST1, ST2, ST3, ST5, and ST6 may be turned on in case that a scan signal of a gate low voltage and a light emission control signal are applied.

In another embodiment, the first to sixth transistors ST1, ST2, ST3, ST4, ST5, and ST6 and the driving transistor DT may all be formed as n-type MOSFET. For example, the active layer of each of the first to sixth transistors ST1, ST2, ST3, ST4, ST5, and ST6 and the driving transistor DT may be formed of an oxide semiconductor and may be turned on in case that a scan signal of a gate high voltage and a light emission control signal are applied.

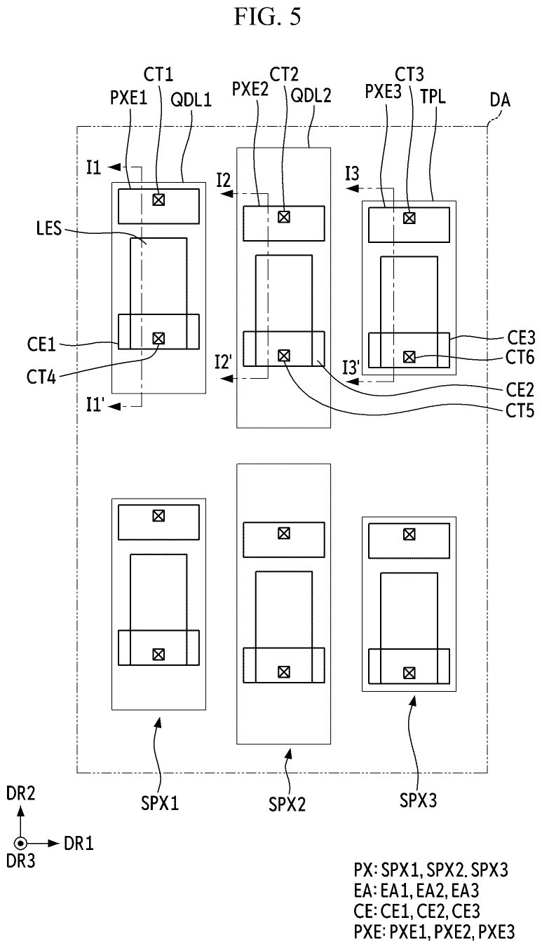

FIG. 5 is a schematic layout illustrating pixels of a display area according to an embodiment.

Referring to FIG. 5, each of multiple pixels PX of the display area DA may include three sub-pixels SPX1, SPX2, and SPX3, but the embodiment of the disclosure is not limited thereto and may include four sub-pixels. In case that each of multiple pixels PX includes three sub-pixels SPX1, SPX2, and SPX3, the first sub-pixel SPX1, the second sub-pixel SPX2, and the third sub-pixel SPX3 may include.

Multiple pixels PX may be arranged in a matrix form. In each of multiple pixels PX, the first sub-pixel SPX1, the second sub-pixel SPX2, and the third sub-pixel SPX3 may be disposed in the first direction DR1.

In case that each of multiple pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from about 370 nm to about 460 nm, the green wavelength band may refer to light having a main peak wavelength in the wavelength band from about 480 nm to about 560 nm, and the red wavelength band may refer to light having a main peak wavelength in the wavelength band from about 600 nm to about 750 nm.

In another embodiment, in case that each of multiple pixels PX includes four sub-pixels, the first sub-pixel may emit light of a first color, the second and fourth sub-pixels may emit light of a second color, and the third sub-pixel may emit light of a third color. In another embodiment, the first sub-pixel may emit light of a first color, the second sub-pixel may emit light of a second color, the third sub-pixel may emit light of a third color, and the fourth sub-pixel may emit light of a fourth color. For example, the fourth color light may be white light.

The first sub-pixel SPX1 may include a first pixel electrode PXE1, a first common electrode CE1, multiple light emitting element structures LES, and a first light conversion layer QDL1. The second sub-pixel SPX2 may include a second pixel electrode PXE2, a second common electrode CE2, multiple light emitting element structures LES, and a second light conversion layer QDL2. The third sub-pixel SPX3 may include a third pixel electrode PXE3, a third common electrode CE3, multiple light emitting element structures LES, and a light transmission layer TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the sub-pixel may become larger as the light conversion efficiency decreases.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

Each of the pixel electrodes PXE1, PXE2, and PXE3 and the common electrodes CE1, CE2, and CE3 may have a rectangular planar shape. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3 but the embodiment of the disclosure is not limited thereto.

In the first sub-pixel SPX1, the first pixel electrode PXE1 and the first common electrode CE1 may be disposed to be spaced apart from each other in the second direction DR2. In the second sub-pixel SPX2, the second pixel electrode PXE2 and the second common electrode CE2 may be disposed to be spaced apart from each other in the second direction DR2. In the third sub-pixel SPX3, the third pixel electrode PXE3 and the third common electrode CE3 may be disposed to be spaced apart from each other in the second direction DR2.

The first common electrode CE1 may be electrically connected to a second power supply line (VSL in FIG. 4) to which a second driving voltage (VSS in FIG. 3) is applied through a first common connection hole (CT4). The second common electrode CE2 may be electrically connected to a second power supply line VSL through a second common connection hole CT5. The third common electrode CE3 may be electrically connected to a second power supply line VSL through a third common connection hole CT6. Therefore, the second power supply voltage VSS may be applied to each of the common electrodes CE1, CE2, and CE3.

Multiple light emitting element structures LES may be disposed on each of the common electrodes CE1, CE2, and CE3. The common electrodes CE1, CE2, and CE3 may not be exposed by the light emitting element structures LES. Multiple light emitting element structures LES may emit light of a third color, for example, light in a blue wavelength band, but the embodiment of the disclosure is not limited thereto. In case that the light emitting element structure LES of the first sub-pixel SPX1 emits light of a first color, the light emitting element structure LES of the second sub-pixel SPX2 emits light of a second color, and the light emitting element structure LES of the third sub-pixel SPX3 emits light of a third color, the light conversion layers QDL1 and QDL2 and the light transmission layer TPL may be omitted.

The first light conversion layer QDL1 may convert or shift the peak wavelength of incident light into light of another specific peak wavelength and emit it. For example, the first light conversion layer QDL1 may convert or shift the third light emitted from multiple light emitting element structures LES of the first sub-pixel SPX1 into the first light.

The second light conversion layer QDL2 may convert or shift the peak wavelength of incident light into light of another specific peak wavelength and emit it. For example, the second light conversion layer QDL2 may convert or shift the third light emitted from multiple light emitting element structures LES of the second sub-pixel SPX2 into the second light.

The light transmission layer TPL may directly transmit the incident light. For example, the light transmission layer TPL may directly transmit the third light emitted from multiple light emitting element structures LES of the third sub-pixel SPX3.

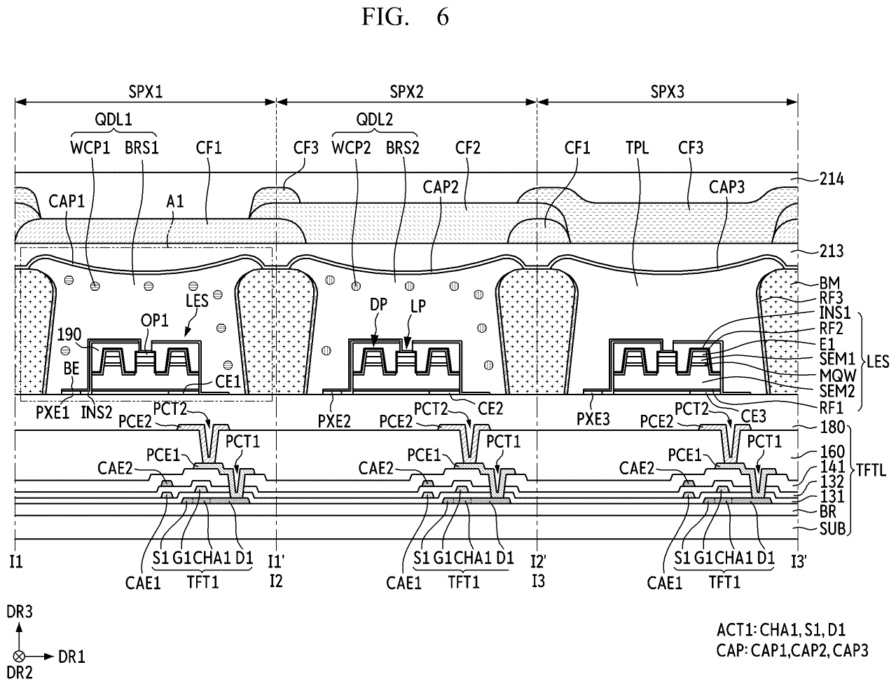

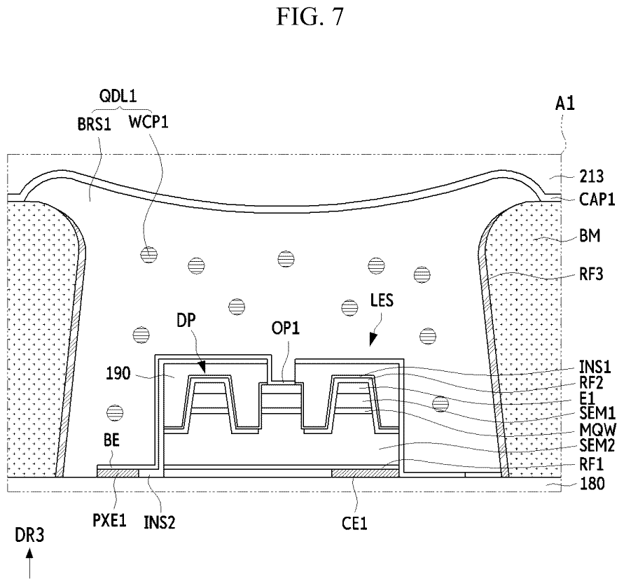

FIG. 6 is a schematic cross-sectional view illustrating an example of a cross-section of a display panel taken along lines I1-I1′, I2-I2′, and I3-I3′ in FIG. 5. FIG. 7 is a schematic cross-sectional view illustrating an example of area A1 of FIG. 6 in detail.

Referring to FIGS. 6 to 7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR may protect the transistors of the thin film transistor layer TFTL and the light emitting element structure LES from moisture penetrating through the substrate SUB which is vulnerable to moisture permeation. The barrier film BR may be composed of multiple inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. In another embodiment, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may overlap the first gate electrode G1 in the third direction DR3, which is the thickness direction of the substrate SUB. The first source area S1 may be disposed on a side of the first channel area CHA1, and the first drain area D1 may be disposed on another side of the first channel area CHA1. The first source area S1 and the first drain area D1 may be areas that do not overlap the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being disposed apart from each other in FIG. 6, the first gate electrode G1 and the first capacitor electrode CAE1 may be electrically connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Since the second gate insulating film 132 has a selected dielectric constant, the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2.

A first data metal layer may be disposed on the first interlayer insulating film 141. The first data metal layer may include a first source connection electrode PCE1. The first source connection electrode PCE1 may be electrically connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 to planarize a step caused by the thin film transistor TFT1.

A second data metal layer may be disposed on the first planarization organic film 160. The second data metal layer may include a second source connection electrode PCE2. The second source connection electrode PCE2 may be electrically connected to the first source connection electrode PCE1 through a second pixel contact hole (PCT2) penetrating the first planarization organic film 160.

A second planarization organic film 180 may be disposed on the second source connection electrode PCE2.

The barrier film BR, the first gate insulating film 131, the second gate insulating film 132, and the interlayer insulating film 141 may be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film such as an acrylic resin, an epoxy resin, a phenolic resin, a polyamide resin, a polyimide resin, or the like.

A light emitting element structure LES may be disposed on the second planarization organic film 180. The light emitting element structure LES may include pixel electrodes PXE1, PXE2, PXE3, light emitting element structures LES, and a common electrode CE.

A pixel electrode layer may be disposed on the second planarization organic film 180. The pixel electrode layer may include pixel electrodes PXE1, PXE2, and PXE3 and common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) having low surface resistance to lower the resistance of each of the pixel electrodes PXE1, PXE2, and PXE3.

The light emitting element structure LES may further include a first reflective layer RF1, multiple semiconductor layers disposed on the first reflective layer RF1, a conductive layer E1, a second reflective layer RF2 covering at least a portion of multiple semiconductor layers, and a first protective layer INS1. The light emitting element LE described in FIGS. 1 to 5 may be the light emitting element structure LES.

The light emitting element structure LES may have a surface directly disposed on the common electrode CE. On the other hand, the light emitting element structure LES may not be in direct contact with the pixel electrode.

The first reflective layer RF1 may be disposed closer to the pixel electrode layer than multiple semiconductor layers.

The first reflective layer RF1 may reflect light emitted downward from the active layer MQW and emit light to the upper surface of the light emitting element structure LES. Therefore, since the light loss of the light emitting element structure LES is reduced, the light efficiency of the light emitting element structure LES may increase.

The first reflective layer RF1 may include a metal material having a high light reflectivity. For example, the first reflective layer RF1 may include aluminum or silver and may also include an alloy thereof.

Multiple semiconductor layers may include a second semiconductor layer SEM2, an active layer MQW, and a first semiconductor layer SEM1 sequentially disposed in the third direction DR3.

The second semiconductor layer SEM2 may be disposed on the first reflective layer RF1. The second semiconductor layer SEM2 may be doped with a second conductive dopant such as Si, Ge, Sn, or the like. For example, the second semiconductor layer SEM2 may be n-GaN doped with n-type Si.

The second semiconductor layer SEM2 may include multiple first portions SEM2_1 having a first thickness T1 and multiple second portions SEM2_2 having a second thickness T2 disposed on the first portion SEM2_1. Multiple second portions SEM2_2 may be alternately disposed on the first portion SEM2_1.

The active layer MQW may be disposed on the second portion SEM2_2 of the second semiconductor layer SEM2. The active layer MQW may emit light by coupling electron-hole pairs according to an electric signal applied through the first semiconductor layer SEM1 and the second semiconductor layer SEM2.

The active layer MQW may include a material having a single or multi-quantum well structure. In case that the active layer MQW includes a material having a multi-quantum well structure, it may have a structure in which multiple well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the disclosure are not limited thereto. In another embodiment, the active layer MQW may have a structure in which semiconductor materials having a high band gap energy and semiconductor materials having a low band gap energy are alternately stacked with each other, may include other Group three to five semiconductor materials according to the wavelength range of emitted light.

In case that the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element structure LES that emits the third light (light in the blue wavelength band) may be about 10 wt % to about 20 wt %.

The first semiconductor layer SEM1 may be disposed on the active layer MQW. The first semiconductor layer SEM1 may be doped with a second conductive dopant, such as Si, Ge, Sn, or the like. For example, the second semiconductor layer SEM2 may be n-GaN doped with n-type Si.

The first semiconductor layer SEM1 may be electrically connected to the pixel electrode PXE of each sub-pixel SPX. For example, the first semiconductor layer SEM1 may be electrically connected to the pixel electrode PXE of each sub-pixel SPX through the conductive layer E1 and the connection electrode BE.

The conductive layer E1 may be disposed on the upper surface of the first semiconductor layer SEM1. In FIG. 7, the conductive layer E1 may be exemplified as covering the entire lower surface of the first semiconductor layer SEM1, but the embodiment of the disclosure is not limited thereto. For example, the conductive layer E1 may be disposed on a portion of the lower surface of the first semiconductor layer SEM1. The conductive layer E1 may include one of molybdenum (Mo), aluminum (Al), chromium (Cr), gold (Au), titanium (Ti), nickel (Ni), neodymium (Nd), and copper (Cu).

In another embodiment, a third semiconductor layer may be further disposed between the second semiconductor layer SEM2 and the first reflective layer RF1. The third semiconductor layer may be a semiconductor material layer having an n-type dopant lower than a selected threshold value and may be referred to as an undoped semiconductor layer. For example, the third semiconductor layer may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is lower than a selected threshold.

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The superlattice layer may be omitted.

The light emitting element structure LES may include a light emitting pillar LP and multiple dummy pillars DP. The dummy pillars DP may be disposed to surround the light emitting pillar LP.

The light emitting pillar LP and the dummy pillars DP may each include a second portion of the second semiconductor layer SEM2_2, an active layer MQW, a first semiconductor layer SEM1, and a conductive layer E1.

The dummy pillar DP and the light emitting pillar LP may be disposed on the same first reflective layer RF1 and second reflective layer SEM2 so that they are electrically connected to each other.

The second reflective layer RF2 may surround the side surface and the upper surface of the dummy pillars DP. On the other hand, the second reflective layer RF2 may not be disposed on the side surface and the upper surface of the light emitting pillar LP.

The second reflective layer RF2 may include a metal material having a high reflectivity of light. For example, the second reflective layer RF2 may include aluminum or silver and may also include an alloy thereof. Further, the second reflective layer RF2 may include M pairs of first and second layers having different refractive indices (M is an integer greater than or equal to 2) to act as Distributed Bragg Reflectors (DBR). For example, the M first layers and the M second layers may be disposed alternately. In the same pair, the first layer may be disposed closer to the inside of the dummy pillar DP than the second layer, and the refractive index of the first layer may be lower than the refractive index of the second layer. The difference between the refractive index of the first layer and the refractive index of the second layer may be 0.55 or more.

The first layer and the second layer may be formed of an inorganic film, such as silicon nitride (SiNₓ), silicon oxide nitride (SiON), silicon oxide (SiOₓ), titanium oxide (TiOₓ), or aluminum oxide (AlOₓ).

The first protective layer INS1 may be disposed on the front surface of the light emitting element structure LES. For example, the first protective layer INS1 may be disposed on the upper surface and side surface of the dummy pillar DP and the upper surface and side surface of the light emitting pillar LP and may be a film for protecting the dummy pillar DP and the light emitting pillar LP.

The first protective layer INS1 may include a first opening OP1 that exposes a conductive layer E1 on the upper surface of the light emitting pillar LP. The conductive layer E1 exposed in the first opening OP1 may be electrically connected to the pixel electrode PXE by contacting a connecting electrode BE described below. The first protective layer INS1 may be formed of an inorganic film, such as silicon nitride (SiNₓ), silicon oxide nitride (SiON), silicon oxide (SiOₓ), titanium oxide (TiOₓ), or aluminum oxide (AlOₓ) but is not limited thereto. The first protective layer INS1 may be a composite film composed of a zirconium oxide film/aluminum oxide film/zirconium oxide film (ZAZ: ZrO₂/Al₂O₃/ZrO₂).

A planarization layer 190 may be disposed on the light emitting element structure LES. For example, the planarization layer 190 having a selected height may be formed on the first protective layer INS1 of the light emitting element structure LES to planarize the step caused by the light emitting pillar LP and the dummy pillar DP.

The planarization layer 190 may be formed to cover both the light emitting pillar LP and the dummy pillar DP. In case that the planarization layer 190 may be formed to cover both the light emitting pillar LP and the dummy pillar DP, the planarization layer 190 may form an opening that overlaps the first opening OP1 of the first protective layer INS1 in the thickness direction (third direction DR3) to expose the conductive layer E1.

The planarization layer 190 may be formed of an inorganic film, such as silicon nitride (SiNₓ), silicon oxide nitride (SiON), silicon oxide (SiOₓ), titanium oxide (TiOₓ), or aluminum oxide (AlOₓ) but is not limited thereto. For example, the planarization layer 190 may also be formed of an organic film.

The light emitting element structure LES may further include a second protective layer INS2 surrounding the upper surface and the side surface.

The second protective layer INS2 may surround the upper surface and the side surface of the planarization layer 190. The second protective layer INS2 may form an opening that overlaps the opening OP1 of the first protective layer INS1 in the thickness direction (third direction DR3) to expose the conductive layer E1.

The second protective layer INS2 may be formed of an inorganic film, such as silicon nitride (SiNₓ), silicon oxide nitride (SiON), silicon oxide (SiOₓ), titanium oxide (TiOₓ), or aluminum oxide (AlOₓ) but is not limited thereto.

The connection electrode BE contacts the conductive layer E1 exposed through the first opening OP1 and extends along the upper surface and side surface of the second protective layer INS2 to contact the pixel electrode PXE. The connection electrode BE may include one of molybdenum (Mo), aluminum (Al), chromium (Cr), gold (Au), titanium (Ti), nickel (Ni), neodymium (Nd), and copper (Cu). In another embodiment, the connection electrode BE may be made of a transparent conductive material (TCO), such as indium tin oxide (ITO) and indium zinc oxide (IZO).

A partition wall BM that partitions each sub-pixel SPX1, SPX2, and SPX3 may be further disposed on the second planarization organic film 180.

The partition wall BM may also be called a light blocking layer in that it includes a light blocking material to prevent light from a light emitting element structure LES of a sub-pixel from traveling to the neighboring sub-pixel.

The partition wall BM may be formed in a grid-like pattern over the entire display area DA. The partition wall BM may not overlap multiple light emitting element structures LES in the third direction DR3. The partition wall BM may serve to provide a space for forming a first light conversion layer QDL1, a second light conversion layer QDL2, and a light transmission layer TPL. The partition wall BM may be formed of an organic insulating material, such as an acrylic resin, epoxy resin, phenolic resin, polyamide resin, polyimide resin, or the like.

The partition wall BM may be formed as a single layer but is not limited thereto. For example, the partition wall BM may be formed as a two layer. The partition wall BM may be formed in two layers to secure sufficient space for forming the first light conversion layer QDL1, the second light conversion layer QDL2, and the light transmission layer TPL.

The partition wall BM may include a light-blocking material as described above. For example, the partition wall BM may include an inorganic black pigment such as carbon black or an organic black pigment.

A third reflective layer RF3 may be disposed inside the space formed by the partition wall BM. The third reflective layer RF3 may be disposed on a side surface of the partition wall BM. The third reflective layer RF3 may include a metal material having a high light reflectivity. For example, the third reflective layer RF3 may include aluminum or silver or may include an alloy thereof.

In the first sub-pixel SPX1, a first light conversion layer QDL1 may be disposed between the partition walls BM and the partition walls BM, in the second sub-pixel SPX2, a second light conversion layer QDL2 may be disposed between the partition walls BM and the partition walls BM, and in the third sub-pixel SPX3, a light transmission layer TPL may be disposed between the partition walls BM and the partition walls BM.

The first light conversion layer QDL1 may convert a portion of the third light (light of a blue wavelength band) incident from the light emitting pillar LP into the first light (light of a red wavelength band). The first light conversion layer QDL1 may include a first base resin BRS1 and first wavelength conversion particles WCP1. The first base resin BRS1 may include a light transmitting organic material. The first wavelength conversion particle WCP1 may convert a portion of the third light (light in the blue wavelength band) incident from the light emitting pillar LP into the first light (light in the red wavelength band).

The second light conversion layer QDL2 may convert a portion of the third light (light in the blue wavelength band) incident from the light emitting pillar LP into the second light (light in the green wavelength band). The second base resin BRS2 may include a second base resin BRS2 and a second wavelength conversion particle WCP2. The second base resin BRS2 may include a light transmitting organic material. The second wavelength conversion particle WCP2 may convert a portion of the third light (light in the blue wavelength band) incident from the light emitting pillar LP into the second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

A capping layer CAP may be disposed on the partition wall BM, the first light conversion layer QDL1, the second light conversion layer QDL2, and the light transmission layer TPL.

The capping layer CAP may be formed of an inorganic film, such as silicon nitride (SiNₓ), silicon oxide nitride (SiON), silicon oxide (SiOₓ), titanium oxide (TiOₓ), or aluminum oxide (AlOₓ). The first light conversion layer QDL1, the second light conversion layer QDL2, and the light transmission layer TPL may be encapsulated by the capping layer CAP.

A fourth organic film 213 may be disposed on the second capping layer CAP2. Multiple color filters CF1, CF2, and CF3 may be disposed on the fourth organic film 213. Multiple color filters CF1, CF2, and CF3 may include first color filters CF1, second color filters CF2, and third color filters CF3.

The first color filter CF1 disposed in the first sub-pixel SPX1 may transmit the first light (light in the red wavelength band) and absorb or block the third light (light in the blue wavelength band). Therefore, the first color filter CF1 may transmit the first light (light in the red wavelength band) that has been converted by the first light conversion layer QDL1 among the third light (light in the blue wavelength band) emitted from the light emitting pillar LP and absorb or block the third light (light in the blue wavelength band) that has not been converted by the first light conversion layer QDL1 Accordingly, the first sub-pixel SPX1 may emit the first light (light in the red wavelength band).

The second color filter CF2 disposed in the second sub-pixel SPX2 may transmit the second light (light in the green wavelength band) and absorb or block the third light (light in the blue wavelength band). Therefore, the second color filter CF2 may transmit the second light (light in the green wavelength band) that has been converted by the first light conversion layer QDL1 among the third light (light in the blue wavelength band) emitted from the light emitting pillar LP and absorb or block the third light (light in the blue wavelength band) that has not been converted by the first light conversion layer QDL1. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting pillar LP passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap the partition wall BM in the third direction DR3.

A fifth organic film 214 may be disposed on multiple color filters CF1, CF2, and CF3 for planarization.

The fourth organic film 213 and the fifth organic film 214 may be formed from an acrylic resin, an epoxy resin, a phenolic resin, a polyamide resin, a polyimide resin, or the like.

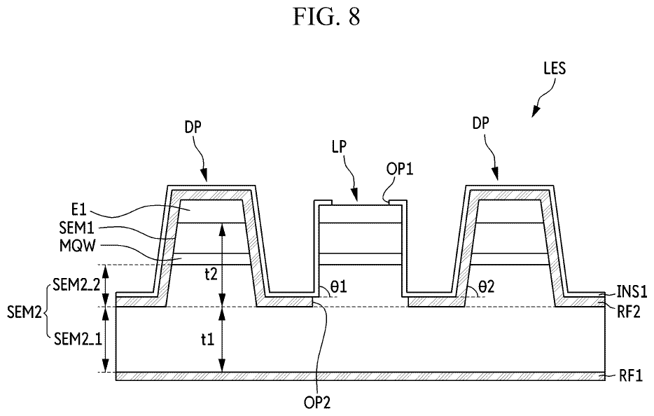

FIG. 8 is a schematic diagram illustrating a light emitting element structure according to an embodiment. The light emitting element structure of FIG. 8 is the light emitting element structure described in the embodiments of FIGS. 6 and 7 so that the overlapping description will not be repeated.

Referring to FIG. 8, the light emitting element structure LES may include a light emitting pillar LP and multiple dummy pillars DP. The light emitting pillar LP may be disposed between adjacent dummy pillars DP interposed therebetween. The light emitting pillar LP may include a second semiconductor layer SEM2, an active layer MQW, a first semiconductor layer SEM1, a conductive layer E1, a second reflective layer RF2, and a first protective layer INS1. The light emitting pillar LP may include a vertical side surface. The width of the upper surface and the width of the lower surface of the light emitting pillar LP may be substantially the same. For example, the light emitting pillar LP may have a substantially rectangular or square cross-sectional shape. The light emitting pillar LP may have a first inclination angle θ1. The first inclination angle θ1 may be an angle between the lower surface of the light emitting pillar LP and the side surface of the light emitting pillar LP. The dummy pillar DP may include a second semiconductor layer SEM2, an active layer MQW, a first semiconductor layer SEM1, a conductive layer E1, a second reflective layer RF2, and a first protective layer INS1. The dummy pillar DP may have a tapered shape with a width that decreases toward the top. The width of the active layer MQW of the dummy pillar DP may be wider than the width of the first semiconductor layer SEM1. The width of the conductive layer E1 of the dummy pillar DP and the width of the conductive layer E1 of the light emitting pillar LP may be the same. The width of the active layer MQW of the dummy pillar DP may be wider than the width of the active layer MQW of the light emitting pillar LP. The dummy pillar DP may have a second inclination angle θ2. The second inclination angle θ2 may be different from the first inclination angle θ1. The second inclination angle θ2 may be smaller than the first inclination angle θ1. The second inclination angle θ2 may be an angle between the lower surface of the dummy pillar DP and the side surface of the dummy pillar DP.

The second reflective layer RF2 may cover the upper surface of the light emitting element structure LES. The second reflective layer RF2 may have a second opening OP2 that exposes the light emitting pillar LP. For example, the second reflective layer RF2 may surround the upper surface and sides of the dummy pillar DP and may not be disposed on the upper surface and sides of the light emitting pillar LP. The second reflective layer RF2 may also be disposed on the second semiconductor layer SEM2 between the dummy pillar DP and the light emitting pillar LP.

The light emitting element structure LES may surround the light emitting pillar LP with dummy pillars DP so that light emitted laterally from the active layer MQW may be reflected to the front by the second reflective layer RF2 surrounding the dummy pillars DP without a separate reflective layer being disposed on the side of the light emitting pillar LP.

As a result, light emitted laterally from the active layer MQW may be minimized from being absorbed and extinguished by the partition wall (BM in FIG. 7) or the like.

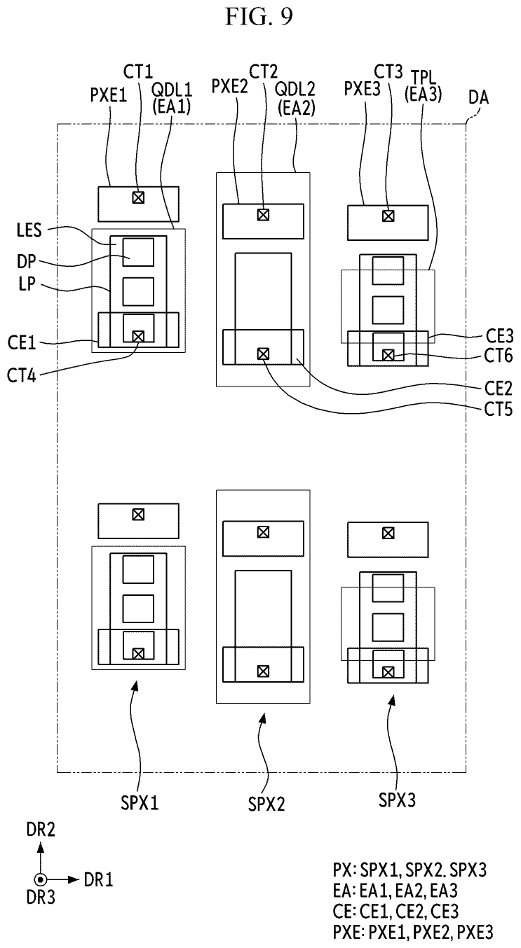

FIG. 9 is a schematic layout diagram illustrating pixels in a display area according to another embodiment.

It is different from FIG. 5 in that the light emitting element structure LES and pixel electrodes PXE3 are disposed outside the light emitting area EA3 of each sub-pixel SPX3. In FIG. 9, the description overlapping the embodiment described with reference to FIG. 5 will not be repeated, and the differences from the embodiment of FIG. 5 will be mainly described.

Referring to FIG. 9, multiple light emitting element structures LES may be disposed on each of the common electrodes CE1, CE2, and CE3.

Some of multiple light emitting element structures LES and the pixel electrodes PXE may be disposed outside the light emitting area EA. For example, the dummy pillar DP of the light emitting element structure LES of a third light emitting area EA3 may be disposed outside the third light emitting area EA3. On the other hand, the light emitting pillar LP may be disposed in the third light emitting area EA3.

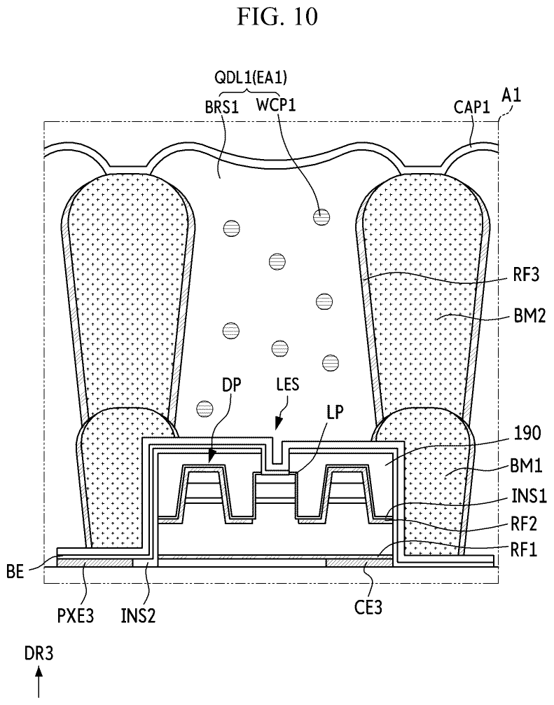

FIG. 10 is a schematic cross-sectional view illustrating an example of a portion of a cross-section of a display panel in a third light emitting area of FIG. 9.

It is different from FIG. 8 in that the light emitting element structure LES and pixel electrodes PXE3 are disposed outside the light emitting area EA3 of each sub-pixel SPX3. In FIG. 10, the description overlapping the embodiment described with reference to FIGS. 6 to 8 will not be repeated, and the differences from the embodiment of FIG. 5 will be mainly described.

The pixel electrode PXE3 and the common electrode CE3 may be disposed spaced apart from each other on the second planarization organic film 180.

The light emitting element structure LES may be disposed on the common electrode CE3 and not on the pixel electrode PXE3.

The pixel electrode PXE3 may overlap the partition walls BM1 and BM2 in the thickness direction DR3.

A portion of the light emitting element structure LES may overlap the partition walls BM1 and BM2 in the thickness direction DR3. For example, a portion of the dummy pillar DP may overlap the partition walls BM1 and BM2.

The partition wall BM may include a first partition wall BM1 and a second partition wall BM2 disposed on the first partition wall BM1. The first partition wall BM1 and the second partition wall BM2 do not overlap the light emitting pillars LP in the third direction DR3.

The second partition wall BM2 may serve to provide a space for forming the first light conversion layer QDL1, the second light conversion layer QDL2, and the light transmission layer TPL.

A third reflective layer RF3 may be disposed inside the space formed by the second partition wall BM2. The third reflective layer RF3 may be disposed on a side surface of the second partition wall BM2.

The first partition wall BM1 and the second partition wall BM2 may include a light blocking material to prevent light from a light emitting pillar LP of one sub-pixel from traveling to an adjacent sub-pixel. For example, the light blocking material may include an inorganic black pigment such as carbon black or an organic black pigment.

The first capping layer CAP1 may be disposed on the second partition wall BM2.

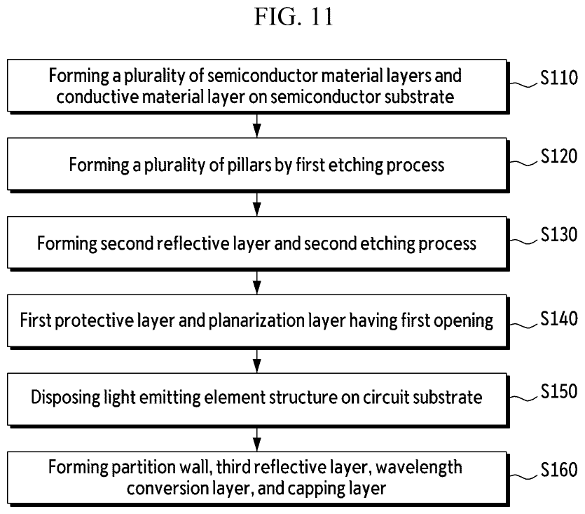

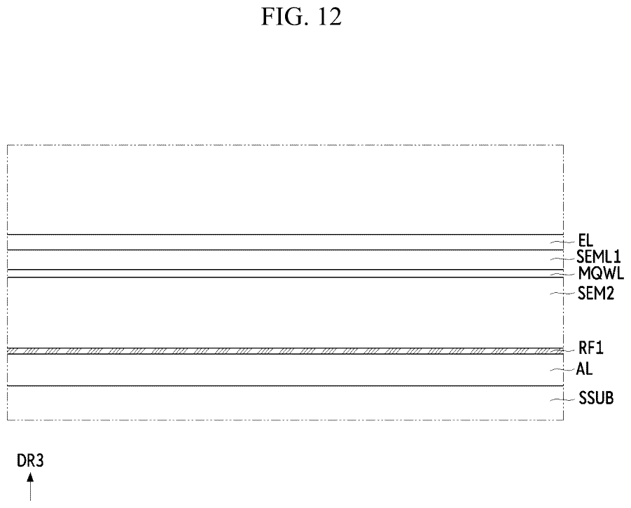

FIG. 11 is a schematic flowchart illustrating a method for manufacturing a display device according to an embodiment. FIGS. 12 to 22 are schematic cross-sectional views illustrating a method for manufacturing a display device according to an embodiment. FIGS. 12 to 22 are drawings corresponding to an embodiment of FIG. 7. FIGS. 12 to 18 focus on the formation of a light emitting element structure according to an embodiment.

In the following, a method for manufacturing a display device illustrated in FIGS. 12 to 22 will be described in conjunction with FIG. 11.

Firstly, as shown in FIG. 12, a second semiconductor layer SEM2, an active layer MQW, a first semiconductor layer SEM1, and a conductive material layer CL may be formed on a semiconductor substrate SSUB. (S110 in FIG. 11) The semiconductor substrate SSUB may be a silicon wafer substrate or a sapphire substrate. A first reflective layer RF1 may be disposed on a side of the semiconductor substrate SSUB. The first reflective layer RF1 may be disposed on the semiconductor substrate SSUB by an adhesive layer AL.

The first reflective layer RF1 may include a metal material having a high light reflectivity. For example, the first reflective layer RF1 may include aluminum or silver and may also include an alloy thereof.

Then, a second semiconductor material layer SEM2 may be formed on the first reflective layer RF1. The second semiconductor material layer SEM2 may be a semiconductor material layer doped with a second conductive dopant such as silicon (Si), germanium (Ge), tin (Sn), or the like.

Then, an active layer MQW may be formed on the second semiconductor layer SEM2, and the first semiconductor layer SEM1 may be formed on the active layer MQW. The active layer MQW may include the same semiconductor material layer as the first semiconductor layer SEM1 and the second semiconductor layer SEM2. For example, in case that the first semiconductor layer SEM1 and the second semiconductor layer SEM2 include gallium nitride (GaN), the active layer MQW may also include gallium nitride (GaN). For example, the active layer MQW may include at least one of gallium nitride (GaN), indium gallium nitride (InGaN), and aluminum gallium nitride (AlGaN). The first semiconductor layer SEM1 may be a semiconductor material layer doped with a first conductive dopant, such as magnesium (Mg), zinc (Zn), calcium (Ca), strontium (Sr), barium (Ba), or the like.

The second semiconductor layer SEM2, the active layer MQW, and the first semiconductor layer SEM1 may be formed on a semiconductor substrate SSUB through an epitaxial growth process. As an epitaxial growth process, the method for forming the second semiconductor layer SEM2, the active layer MQW, and the first semiconductor layer SEM1 may be utilized electron beam vapor deposition, physical vapor deposition (PVD), chemical vapor deposition (CVD), plasma laser deposition (PLD), dual-type thermal evaporation, sputtering, metal organic chemical vapor deposition (MOCVD), and the like. Preferably, metal organic chemical vapor deposition (MOCVD) may be used, but the embodiments of the disclosure are not limited thereto.

Then, a conductive material layer EL may be formed on the first semiconductor layer SEM1. The conductive material layer EL may be formed of one of molybdenum (Mo), aluminum (Al), chromium (Cr), gold (Au), titanium (Ti), nickel (Ni), neodymium (Nd), and copper (Cu).

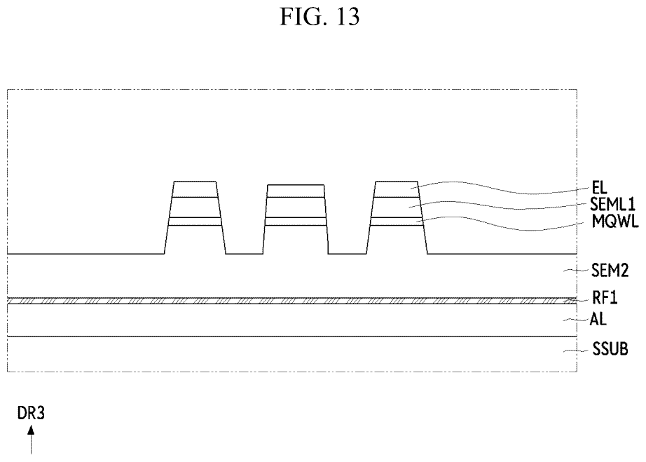

Secondly, as shown in FIG. 13, the second semiconductor layer SEM2, the active layer MQW, the first semiconductor layer SEM1, and the conductive material layer EL may be first etched to form multiple light emitting pillars LP. (S120 in FIG. 11)

For example, after forming a mask pattern on the conductive material layer EL, the second semiconductor layer SEM2, the active layer MQW, the first semiconductor layer SEM1, and the conductive material layer EL may be first etched and patterned according to the mask pattern. The first etching may be dry etching. Multiple light emitting pillars LP having a second inclination angle θ2 (see FIG. 8) may be formed by a dry etching process. In case that a dry etching process is used, the etching gas may be chlorine (Cl₂) or oxygen (O₂) gas but is not limited thereto.

The smaller the second inclination angle θ2 of the dummy pillar DP may be the wider the viewing angle, and the larger the second tilt angle θ2 (see FIG. 8) may be the higher the light emission efficiency.

Since the second inclination angle θ2 may be controlled by adjusting the process conditions of the first etching process, the second inclination angle θ2 (see FIG. 8) may be determined according to the viewing angle or light emission efficiency.

At least a portion of the second semiconductor layer SEM2 may be patterned. The thickness t1 of the unpatterned second semiconductor layer SEM2 may be about 400 nm to about 900 nm. The thickness t2 of the patterned semiconductor layer SEM2, MQW, and SEM1 may be about 600 nm.

The mask pattern may be removed after forming multiple light emitting pillars LP.

Thirdly, a second reflective layer RF2 may be formed, and a second etching process may be performed. (S130 in FIG. 11)

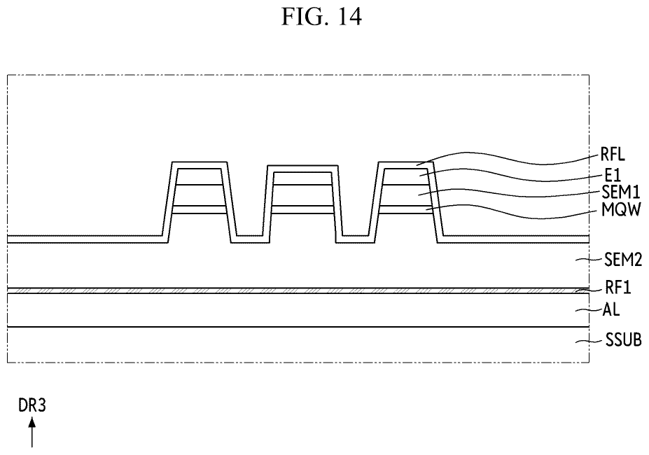

Referring to FIG. 14, a reflective material layer RFL may be formed on the entire surface of the semiconductor substrate SSUB. The reflective material layer RFL may be deposited by a process such as a stuffer but is not limited thereto.

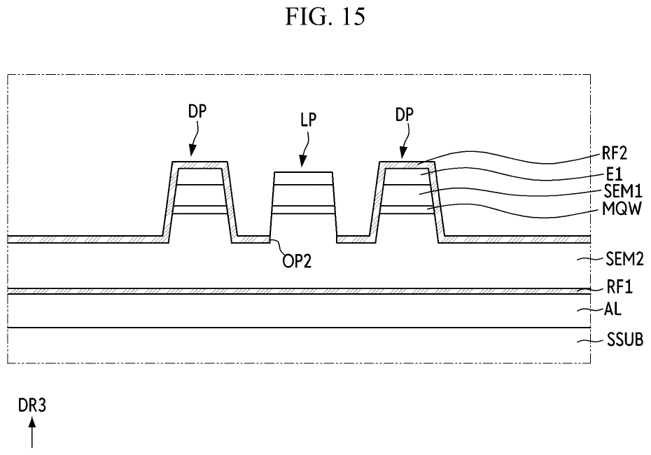

Then, referring to FIG. 15, a reflective material layer RFL of some of the pillars DP may be formed. Some of the pillars DP from which the reflective material layer RFL is removed become light emitting pillars LP, and the remaining pillars DP with the second reflective layer RF2 remaining may become dummy pillars DP.

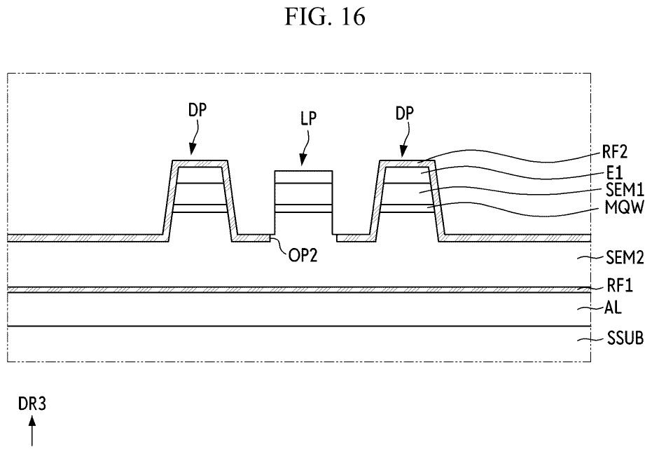

Referring to FIG. 16, the light emitting pillars LP may be etched for the second time to form an inclined surface having a first inclination angle θ1. The second etching may be wet etching. The light emitting pillars LP having a first inclination angle θ1 (see FIG. 8) may be formed by a wet etching process. In case that using a wet etching process, the etchant may be tetramethylammonium hydroxide (TMAH) but is not limited thereto.

The first protective layer INS1 may function as a mask. Therefore, as shown in FIG. 16, the dummy pillar DP surrounded by the first protective layer INS1 may not be etched, and only the light emitting pillar LP may be etched. Therefore, the inclination angles of the dummy pillar DP and the inclination angles of the light emitting pillar LP may be different from each other. For example, the dummy pillar DP may have a second inclination angle θ2, and the inclination angle of the light emitting pillar LP may have a first inclination angle θ1.

Fourthly, the first protective layer INS1 having a first opening OP1 and the planarization layer 190 may be formed. (S140 in FIG. 11)

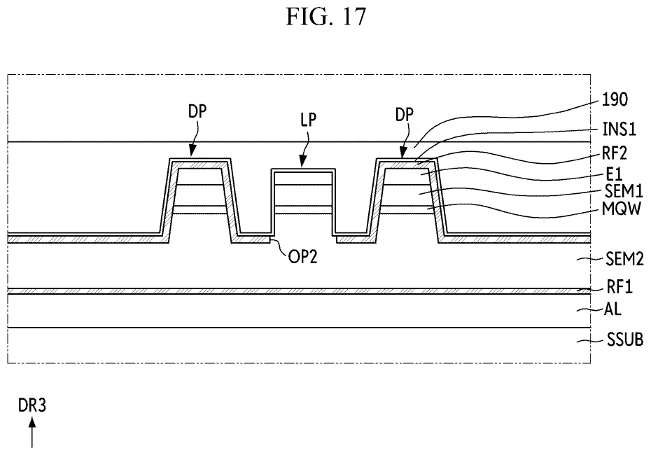

As shown in FIG. 17, a first protective layer INS1 may be formed to cover the dummy pillar DP and the light emitting pillar LP covered with the second reflective layer RF2.

For example, a protective material layer may be deposited (or entirely deposited) on a surface of a semiconductor substrate SSUB. The protective material layer may be formed to cover a surface and side surfaces of the dummy pillar DP and the light emitting pillar LP. The protective material layer may be formed on a surface of the semiconductor substrate SSUB exposed between the dummy pillar DP and the light emitting pillar LP.

Then, an insulating material layer may be formed on a surface of the semiconductor substrate SSUB to planarize it.

The insulating material layer may be formed to cover all the dummy pillars DP and the light emitting pillars LP. The insulating material layer may become a planarization layer 190.

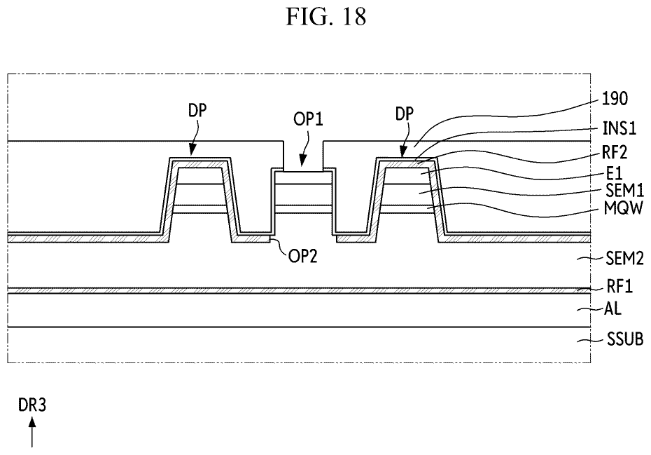

As shown in the following FIG. 18, the first protective layer INS1 and the planarization layer 190 may be removed from the upper surface of the light emitting pillar LP to form a first opening OP1. At least a portion of the conductive layer E1 may be exposed by the first opening OP1.

Fifthly, the light emitting element structure LES formed by the process of the aforementioned steps S110 to S140 may be disposed on a circuit substrate. (S150 in FIG. 11)

The light emitting element structure LES formed by the process of the aforementioned steps S110 to S140 may be separated from the semiconductor substrate SSUB.

The circuit substrate may be a circuit substrate described with reference to FIG. 6, and a thin film transistor layer TFTL and a circuit electrode layer may be formed on the substrate SUB.

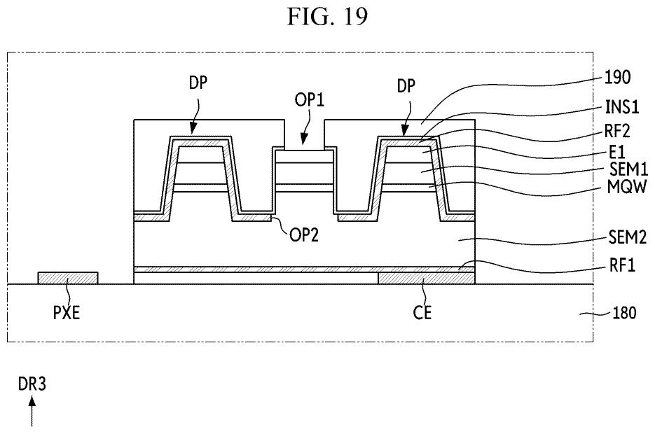

For example, as shown in FIG. 19, at least a surface of at least the first reflective layer RF1 of the light emitting element structure LES may be disposed on the common electrode CE.

Sixthly, the second protective layer INS2 and the connection electrode BE may be formed.

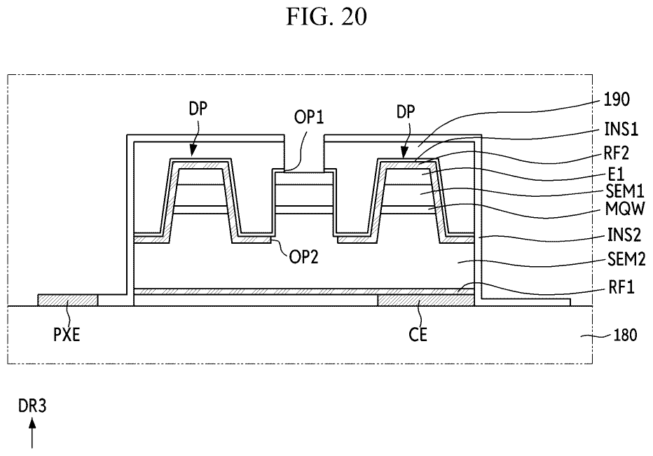

As shown in FIG. 20, the protective material layer may be formed to cover the entire surface of the circuit substrate, and then the second protective layer INS2 may be formed by partially etching through a photo process.

The photo process may be a process for forming a desired structure by applying photoresist PR on a substrate and then passing light through a mask formed in a desired pattern. For example, the photoresist may be formed to cover the light emitting element structure LES. Accordingly, the second protective layer INS2 may be formed to cover both the upper surface and the side surface of the light emitting element structure LES but may not cover the pixel electrode PXE. Furthermore, an opening may be formed in an area overlapping the first opening OP1 of the light emitting pillar LP of the second protective layer INS2 through additional etching, thereby exposing the conductive layer E1 of the light emitting pillar LP.

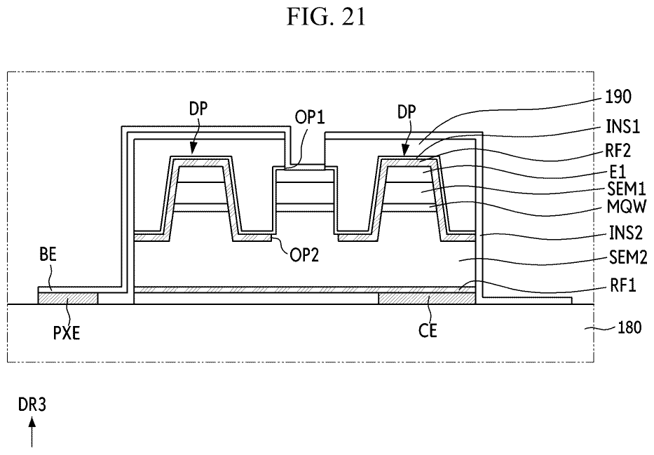

Then, as shown in FIG. 21, a connection electrode BE connecting the conductive layer E1 exposed by the first opening OP1 of the light emitting pillar LP and the pixel electrode PXE may be formed.

To form the connection electrode BE, for example, a conductive material layer may be deposited over the entire circuit substrate, and a portion of the conductive material layer deposited in an unnecessary area may be etched to form the connection electrode BE. The connection electrode BE may be extended along the second protective layer INS2 on the conductive layer E1 of the light emitting pillar LP and may be disposed on the upper surface of the pixel electrode PXE.

Seventhly, a partition wall BM, a third reflective layer BF3, a wavelength conversion layer QDL, and a capping layer CAP may be formed sequentially. (S160 in FIG. 11)

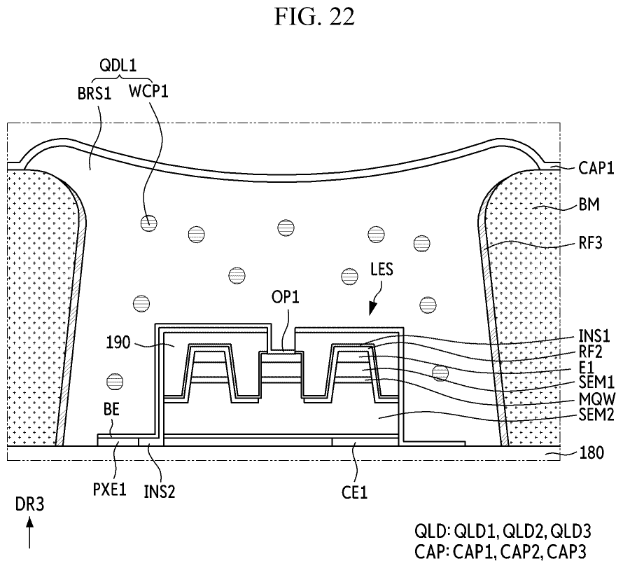

Referring to FIG. 22, the partition wall BM may be formed on the second planarization organic film 180. For example, a negative-type photoresist is used to form the partition wall BM on the second planarization organic film 180. Since the negative photoresist dissolves in a portion that is not exposed to light, the partition wall BM may be formed in an inverted tapered shape that narrows in width toward the bottom.

A reflective material layer may be deposited on the entire surface of the circuit substrate on which the partition wall BM may be formed. After that, a portion of the reflective material layer is partially etched to form a third reflective layer RF3 on the side of the partition wall BM.

The method of partially etching may be similar to that described with reference to FIGS. 18 and 19 so that a detailed description is omitted.

A first light conversion layer QDL1 may be formed on each of the first sub-pixels SPX1, a second light conversion layer QDL2 may be formed on each of the second sub-pixels SPX2, and a light transmission layer TPL may be formed on each of the third sub-pixels SPX3. Then, a first capping layer CAP1 may be formed covering the first light conversion layers QDL1, the second light conversion layers QDL2, and the light transmission layers TPL.

After that, a color filter layer may be further formed as needed.

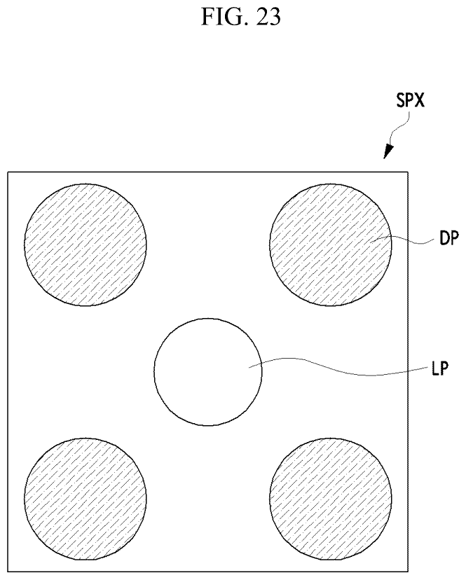

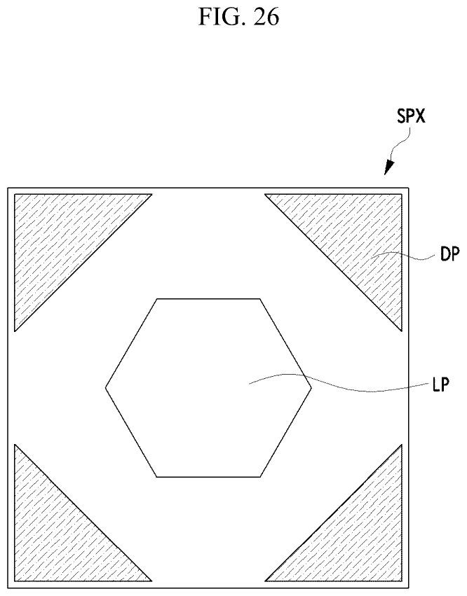

FIGS. 23 to 26 are schematic plan views illustrating positions of dummy pillars and light emitting pillars in a sub-pixel according to an embodiment.

Referring to FIGS. 23 to 26, dummy pillars DP may be disposed to surround the light emitting pillar LP. For example, in case that the sub-pixel SPX is rectangular, the light emitting pillar LP may be disposed in the center, and four dummy pillars DP may be disposed at each corner of the rectangular shape.

Referring to FIG. 23, the dummy pillars DP may have the same shape as the light emitting pillar LP in a plan view. For example, all the dummy pillars DP may be circular in a plan view, but the disclosure is not limited thereto.

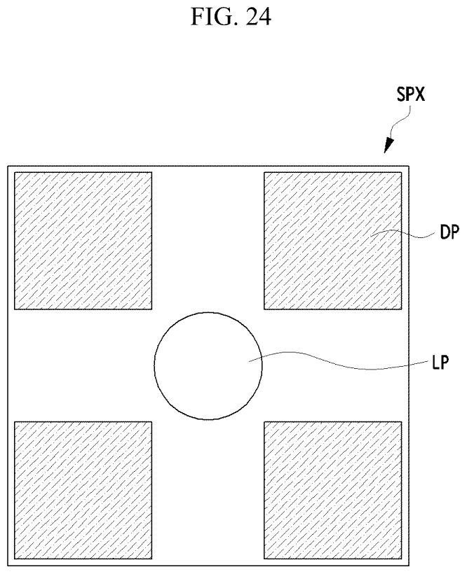

Referring to FIGS. 24 to 26, the dummy pillars DP may be different from the light emitting pillar LP in a plan view.

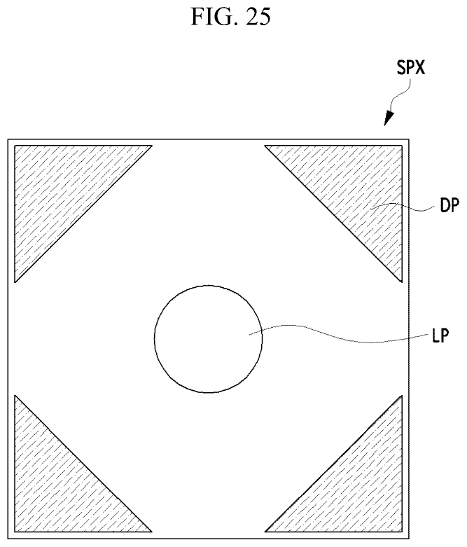

For example, as shown in FIG. 24, the light emitting pillar LP disposed in the center of the sub-pixel SPX may be circular in a plan view, and the dummy pillars DP disposed at each corner may be rectangular. In another embodiment, as shown in FIG. 25, the light emitting pillar LP disposed at the center of the sub-pixel SPX may be circular in a plan view, and the dummy pillars DP disposed at each corner may be triangular. As another example, as shown in FIG. 25, the light emitting pillar LP disposed at the center of the sub-pixel SPX may be hexagonal in a plan view, and the dummy pillars DP disposed at each corner may be triangular. In case that the dummy pillars DP are triangular, the hypotenuse L of the triangle may face the light emitting pillar DP.

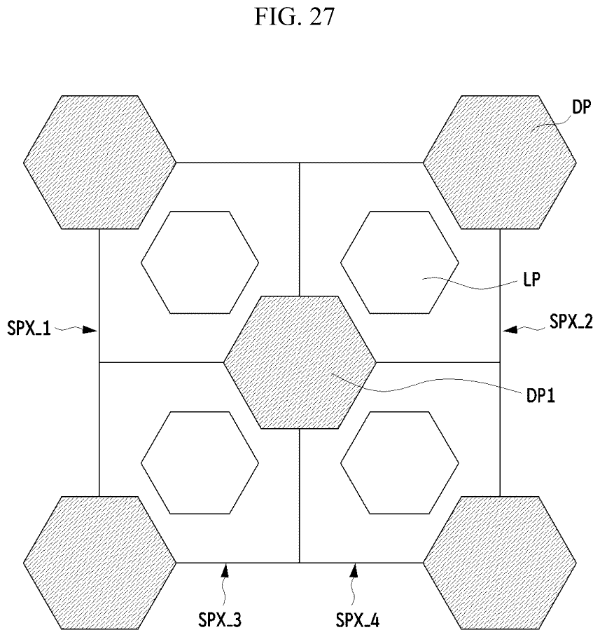

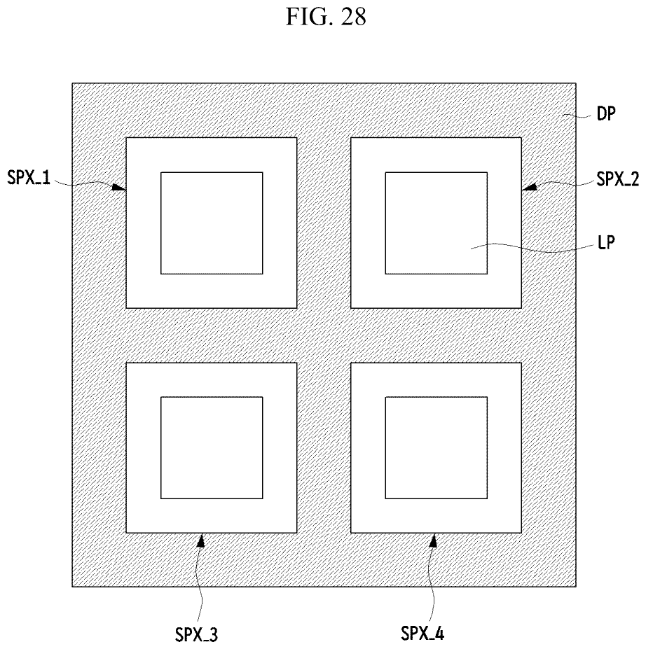

FIGS. 27 and 28 are schematic plan views illustrating positions of dummy pillars and light emitting pillars in a sub-pixel according to another embodiment.

Referring to FIG. 27, four sub-pixels may be disposed, and a light emitting pillar LP may be disposed at the center of each sub-pixel. The light emitting pillar LP and the dummy pillar DP may have the same shape in a plan view, but are not limited thereto, and may have different planes. The dummy pillar DP may have a larger area than the light emitting pillar LP.

The dummy pillar DP may be disposed to overlap multiple sub-pixels at points where vertices of neighboring sub-pixels meet. For example, the first dummy pillar DP1 may be disposed at each vertex of a first sub-pixel SPX_1, a second sub-pixel SPX_2, a third sub-pixel SPX_3, and a fourth sub-pixel SPX_4.

For example, the light emitting pillar LP may be disposed at the center of the sub-pixel SPX, and multiple dummy pillars DP surround the light emitting pillar LP.

Referring to FIG. 28, the dummy pillar DP may be disposed to continuously surround the light emitting pillar DP. As shown in FIGS. 27 and 28, in some embodiments, the dummy pillar DP may be disposed outside the sub-pixel SPX. In such a case, at least a portion of the dummy pillar DP may overlap the partition wall (BM of FIGS. 6 and 7) of the sub-pixel SPX.

The display device according to one embodiment of the present disclosure can be applied to various electronic devices. The electronic device according to the one embodiment of the present disclosure includes the display device described above, and may further include modules or devices having additional functions in addition to the display device.

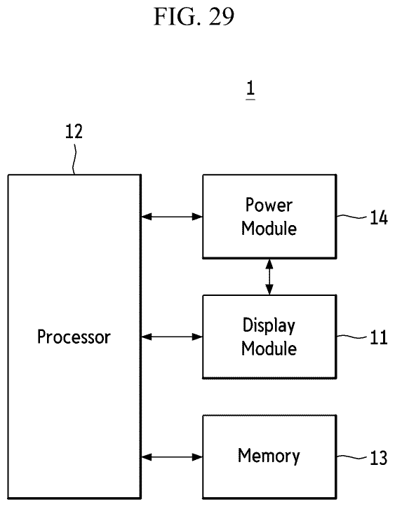

FIG. 29 is a block diagram of an electronic device according to one embodiment of the present disclosure.

Referring to FIG. 29, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

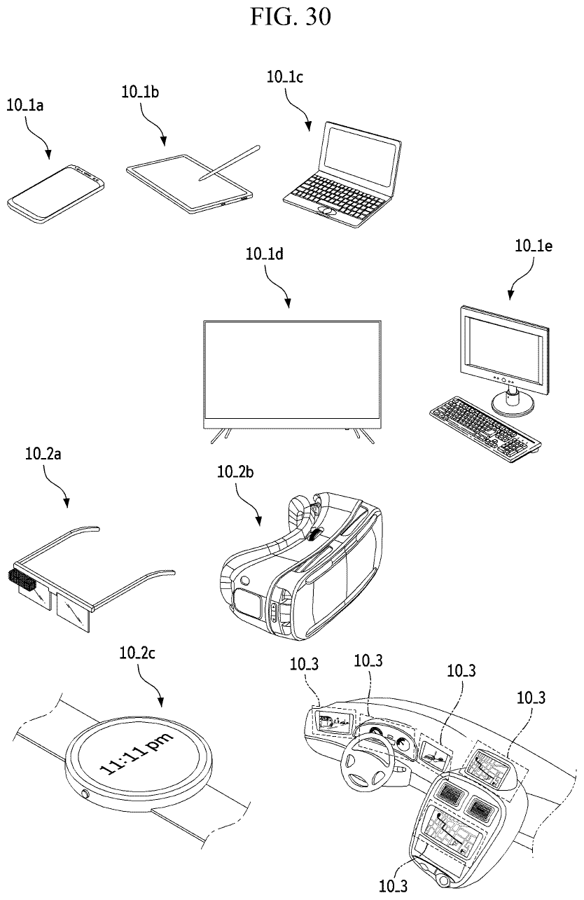

FIG. 30 is a schematic diagram of an electronic device according to various embodiments of the present disclosure.

Referring to FIG. 30, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

It should be understood, however, that the aspects and features of embodiments of the disclosure are not restricted to the one set forth herein. The above and other aspects of the disclosure will become more apparent to one of ordinary skill in the art to which the disclosure pertains by referencing the claims, with equivalents thereof to be included therein.

What is claimed is:

1. A display device comprising:
a substrate;
a pixel electrode and a common electrode disposed on the substrate disposed apart from each other on the substrate;
a light emitting element structure disposed on the common electrode, and including a light emitting pillar and a plurality of dummy pillars surrounding the light emitting pillar; and
a connection electrode connecting the light emitting pillar and the pixel electrode,
wherein the light emitting element structure includes:
a reflective layer surrounding an upper surface and a side surface of the dummy pillar; and
a protective layer surrounding the upper surface and the side surface of the dummy pillar and an upper surface and a side surface of the light emitting pillar.

2. The display device of claim 1, wherein
the light emitting pillar has a first inclination angle between a lower surface and a side surface of the light emitting pillar,
the dummy pillar has a second inclination angle that is between the lower surface and the side surface of the dummy pillar, and
the second inclination angle is different from the second inclination angle.

3. The display device of claim 2, wherein the second inclination angle is smaller than the first inclination angle.

4. The display device of claim 1, wherein
a width of the dummy pillar decreases as a distance from the substrate increases on the substrate, and
the upper surface and a lower surface of the light emitting pillar have a same width.

5. The display device of claim 1, wherein the light emitting element structure further includes:
an element reflective layer on a lower surface;
a plurality of semiconductor layers disposed on the element reflective layer; and
a conductive layer disposed on the plurality of semiconductor layers.

6. The display device of claim 5, wherein the plurality of semiconductor layers include:
a second semiconductor layer including a first portion having a first height and a second portion having a second height on the first portion;
an active layer disposed on the second semiconductor layer; and
a first semiconductor layer disposed on the active layer.

7. The display device of claim 6, wherein the dummy pillar and the light emitting pillar each include a second semiconductor layer including the second portion, the active layer, the first semiconductor layer, and the conductive layer.

8. The display device of claim 7, wherein
the protective layer includes an opening exposing a portion of the conductive layer of the light emitting pillar, and
the connection electrode is electrically connected to the conductive layer through the opening.

9. The display device of claim 1, further comprising:
a planarization layer disposed on the light emitting element structure; and
a second protective layer disposed on an upper surface of the planarization layer and a side surface of the light emitting element structure and having an opening overlapping an opening of the protective layer.

10. The display device of claim 1, further comprising:
a partition wall disposed to surround the light emitting element structure;
a third reflective layer disposed on a side surface of the partition wall; and
a wavelength conversion layer disposed in a space formed by the partition wall.

11. The display device of claim 10, wherein the light emitting element structure does not overlap the partition wall.

12. The display device of claim 10, wherein the light emitting element structure does not overlap the light emitting pillar but overlaps a portion of the dummy pillar.

13. The display device of claim 1, wherein
the dummy pillar is circular or polygonal in a plan view, and
the light emitting pillar is circular or polygonal in a plan view.

14. The display device of claim 13, wherein the dummy pillar and the light emitting pillar have a same shape in a plan view.

15. The display device of claim 13, wherein the dummy pillar and the light emitting pillar have different shapes in a plan view.

16. A method for manufacturing a display device, the method comprising:
forming a second semiconductor material layer, an active material layer, a first semiconductor material layer, and a conductive material layer on a semiconductor substrate;
first etching the second semiconductor material layer, the active material layer, the first semiconductor material layer, and the conductive material layer to form a plurality of pillars each including the second semiconductor material layer, the active material layer, the first semiconductor material layer, and the conductive material layer;
forming a reflective layer including openings in some of the pillars among the plurality of pillars, and second etching the pillars on which the reflective layer is not disposed; and
forming a protective layer including an opening on entire surface of the semiconductor substrate on the pillars on which the reflective layer is not disposed.

17. The method of claim 16, wherein the first etching is dry etching, and the second etching is wet etching.

18. The method of claim 16, wherein
among the plurality of pillars, the pillars whose upper surfaces and side surfaces are surrounded by the reflective layer are dummy pillars, and the pillars on which the upper surfaces and the side surfaces are not formed by the openings are light emitting pillars, and
the light emitting pillars and the dummy pillars have different inclinations by the second etching.

19. The method of claim 18, further comprising:
separating a light emitting element structure including the light emitting pillar and the dummy pillar from the semiconductor substrate and transferring the light emitting pillar and the dummy pillar onto a circuit substrate including a pixel electrode and a common electrode; and
forming a connection electrode connecting the pixel electrode and the light emitting pillars.

20. An electronic device comprising:
a display panel including:
a substrate;
a pixel electrode and a common electrode disposed on the substrate disposed apart from each other on the substrate;
a light emitting element structure disposed on the common electrode, and including a light emitting pillar and a plurality of dummy pillars surrounding the light emitting pillar; and
a connection electrode connecting the light emitting pillar and the pixel electrode,
wherein the light emitting element structure includes:
a reflective layer surrounding an upper surface and a side surface of the dummy pillar; and
a protective layer surrounding the upper surface and the side surface of the dummy pillar and an upper surface and a side surface of the light emitting pillar.
